(19) United States
(12) Patent Application Publication
(10) Pub. No.: US 2025/0270699 A1
(43) Pub. Date: Aug. 28, 2025

(54) VALVE DEVICE, SUBSTRATE PROCESSING APPARATUS, AND SUBSTRATE PROCESSING METHOD

(71) Applicant: Tokyo Electron Limited, Tokyo (JP)

(72) Inventor: Tsutomu HIROKI, Nirasaki City (JP)

(21) Appl. No.: 19/055,721

(22) Filed: Feb. 18, 2025

(30) Foreign Application Priority Data
Feb. 26, 2024 (JP) 2024-026151

(51) Int. Cl. C23C 16/455; C23C 16/44; C23C 16/52

(52) U.S. Cl. CPC C23C 16/45561; C23C 16/4412; C23C 16/45544; C23C 16/52

(57) ABSTRACT

A valve device provided in a processing apparatus including a processing container for processing a workpiece, the valve device includes: a valve body including a valve main body configured to open or close an exhaust path connected to an exhaust port that opens into the processing container and a mover provided in the valve main body to move between a first position at the exhaust path and a second position upstream of the first position and outside the exhaust port; and a detector including a detection part provided in the mover to detect an internal state of the processing container while the mover is at the second position.

### CROSS-REFERENCE TO RELATED APPLICATION

This application is based upon and claims the benefit of priority from Japanese Patent Application No. 2024-026151, filed on Feb. 26, 2024, the entire contents of which are incorporated herein by reference.

### TECHNICAL FIELD

The present disclosure relates to a valve device, a substrate processing apparatus, and a substrate processing method.

### BACKGROUND

In a semiconductor manufacturing apparatus that performs processing on a substrate as a workpiece, there is a step of performing film formation on the substrate inside a processing container by supplying a gas from a gas supplier, which is positioned to face a stage, to the substrate placed on the stage, and reducing an internal pressure of the processing container. The gas inside the processing container is exhausted through an exhaust path that is opened or closed by a valve. In relation to this type of film formation performed on the substrate, Patent Document 1 proposes a technique where an endoscope is inserted into a vacuum chamber to observe film formation in progress while a film is being formed on the substrate inside the vacuum chamber. It is described that the endoscope is connected to a bellows, enabling horizontal movement thereof by extension and contraction of the bellows.

### PRIOR ART DOCUMENTS

### Patent Documents

Patent Document 1: Japanese Laid-Open Publication No. H 08-193964

### SUMMARY

According to one embodiment of the present disclosure, a valve device, provided in a processing apparatus including a processing container for processing a workpiece, includes: a valve body including a valve main body configured to open or close an exhaust path connected to an exhaust port that opens into the processing container and a mover provided in the valve main body to move between a first position at the exhaust path and a second position upstream of the first position and outside the exhaust port; and a detector including a detection part provided in the mover to detect an internal state of the processing container while the mover is at the second position.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical cross-sectional view illustrating a configuration example of a substrate processing apparatus including a valve device.

FIG. 2 is a vertical cross-sectional view illustrating a configuration example of the substrate processing apparatus during substrate processing.

FIG. 3 is a plan view illustrating a configuration example of the substrate processing apparatus.

FIG. 4 is a vertical cross-sectional view illustrating a first embodiment of the valve device.

FIG. 5 is a perspective view illustrating the first embodiment of the valve device.

FIG. 6 is a vertical cross-sectional view illustrating an operation in an open state of the valve device.

FIG. 7 is a vertical cross-sectional view illustrating an operation at another position in the open state of the valve device.

FIG. 8 is a vertical cross-sectional view illustrating the first embodiment of the valve device.

FIG. 9 is a vertical cross-sectional view illustrating an example of detecting a lower end of a gas supplier by a detection part.

FIG. 10 is a vertical cross-sectional view illustrating an example of detecting a height of a stage by the detection part.

FIG. 11 is a plan view illustrating an example of detection by the detection part.

FIG. 12 is a vertical cross-sectional view illustrating a detection operation by the detection part.

FIG. 13 is a vertical cross-sectional view illustrating a detection operation by the detection part.

FIG. 14 is a plan view illustrating another example of detection by the detection part.

FIG. 15 is a plan view illustrating another example of detection by the detection part.

FIG. 16 is a vertical cross-sectional view illustrating a second embodiment of the valve device.

FIG. 17 is a vertical cross-sectional view illustrating another example of the second embodiment of the valve device.

FIG. 18 is a vertical cross-sectional view illustrating a first modification of the valve device.

FIG. 19 is a vertical cross-sectional view illustrating a second modification of the valve device.

FIG. 20 is a vertical cross-sectional view illustrating another example of a valve body.

FIG. 21 is a vertical cross-sectional view illustrating another configuration example of the valve device.

FIG. 22 is a plan view illustrating another configuration example of the valve device.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Substrate Processing Apparatus>

The present disclosure relates to a processing apparatus including a processing container for processing a workpiece, in which an exhaust path extending into the processing container is opened or closed by a valve device, and the valve device is provided with a detection part to detect an internal state of the processing container.

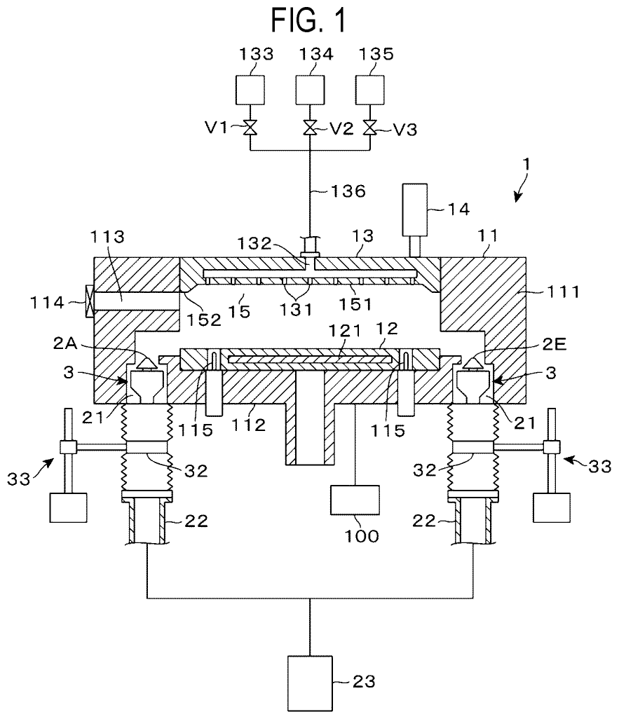

First, a configuration example of the processing apparatus according to the present disclosure is described with reference to FIG. 1 by using an example where it is applied to a substrate processing apparatus that performs film formation by atomic layer deposition (ALD) on a semiconductor wafer (hereinafter referred to as “wafer”) W, which is a substrate serving as the workpiece.

As illustrated in FIG. 1, the substrate processing apparatus 1 includes a processing container 11 that accommodates and processes the wafer W. The processing container 11 is formed into a rectangular shape in a plan view, for example, and a stage 12 on which the wafer W is placed is provided in an interior of the processing container 11. The stage 12 is circular in a plan view and includes an embedded heater 121. A gas supplier 13 is disposed in a region facing the stage 12 inside the processing container 11.

The gas supplier 13 is configured to supply a process gas toward the wafer W placed on the stage 12 in order to process the wafer W. The gas supplier 13 in this example is configured to discharge the process gas in a form of shower toward the stage 12 from multiple outlets 131 formed at a lower surface thereof. However, a configuration of the gas supplier 13 is not limited to this example. For example, the gas supplier 13 may be configured to include a single outlet at a center of the lower surface thereof, instead of providing the multiple outlets 131.

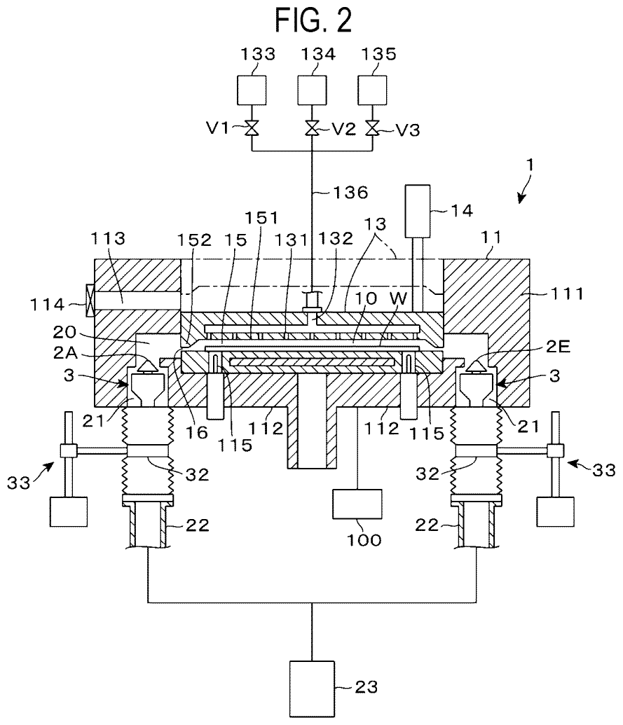

The gas supplier 13 constitutes an upper structure and is oriented to face the stage 12 from above. Then, the gas supplier 13 is configured to be capable of moving up and down by a lift 14 between a transfer position (see FIG. 1) for transferring the wafer W into or out of the processing container 11 and a processing position (see FIG. 2) below the transfer position for processing the wafer W. The lift 14 also serves as a distance changer that changes a distance between the stage 12 and the upper structure (gas supplier 13), which is described later.

The gas supplier 13 is formed into a circular shape in a plan view, for example, and a periphery thereof is surrounded by a sidewall 111 of the processing container 11. An upper surface of the gas supplier 13 is formed as a flat surface. When the gas supplier 13 is at the transfer position, as illustrated in FIG. 1, height positions of an upper surface of the sidewall 111 of the processing container 11 and the upper surface of the gas supplier 13 are aligned. In this way, the processing container 11 is defined by the gas supplier 13 serving as the upper structure, the sidewall 111, and a bottom wall 112.

A circular recess 15 is formed on the lower surface of the gas supplier 13. The recess 15 includes, for example, a flat facing area 151, which faces the wafer W on the stage 12, and an outer perimeter area 152 around the facing area 151, which is formed as an annular flat surface at a lower height position than the facing area 151. The above-described outlets 131 are opened at the facing area 151.

In this way, when the gas supplier 13 is at the processing position, as illustrated in FIG. 2, a processing space 10 for the wafer W is created between the recess 15 of the gas supplier 13 and the stage 12. At this time, a gap 16 is created between the annular flat surface of the perimeter area 152 and an upper surface of the stage 12. When viewed from the wafer W on the stage 12, the gap 16 is formed to laterally surround the wafer W.

A size of the gap 16 when the gas supplier 13 is at the processing position, i.e., a distance between a lower end of the perimeter area 152 and the upper surface of the stage 12, is 1 mm, for example.

The substrate processing apparatus 1 in this example is configured to alternately supply, for example, two types of gases as the process gas to the processing container 11 to perform film formation on the wafer W by ALD. To this end, a raw material gas source 133, a reactant gas source 134, and a replacement gas source 135 are connected to a gas supply port 132 of the gas supplier 13 through a supply path 136. An upstream of the supply path 136 branches into supply paths, which are equipped respectively with valves V1, V2 and V3, and is connected to the respective sources 133, 134 and 135. The process gas in this example includes a raw material gas, a reactant gas, and a replacement gas.

Further, a transfer port 113, through which the wafer W is loaded or unloaded into or from the processing container 11 when the gas supplier 13 is at the transfer position, is formed at the sidewall 111 of the processing container 11. The transfer port 113 is configured to be capable of being opened or closed by a shutter 114. Furthermore, the processing container 11 is provided with a delivery pin 115, which is movable up and down to deliver the wafer W between an external transfer mechanism (not illustrated) and the stage 12.

The processing container 11 includes a plurality of exhaust ports 2 (2A to 2H) that open into the processing container 11. In this example, as illustrated in FIGS. 1 and 2, the exhaust ports 2 are formed at a lateral side of the stage 12 to open upward at a height position lower than the upper surface of the stage 12.

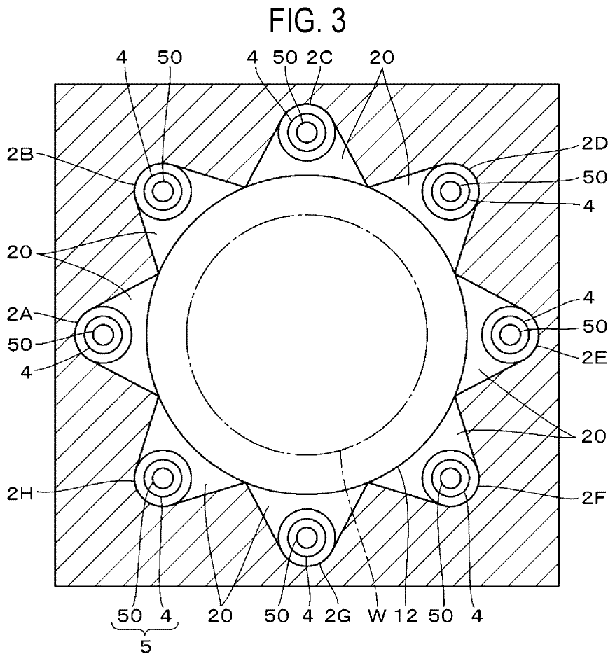

The exhaust ports 2 (2A to 2H) are circular in a plan view, and for example, as illustrated in FIG. 3, are formed in a plural number, for example, eights along a circumferential direction of the stage 12. These exhaust ports 2 are disposed at equally spaced positions around the stage 12. The sidewall 111 is provided with an exhaust path 21, which is connected to each of the exhaust ports 2 and is specifically formed to extend downward from the exhaust ports 2. A downstream of each exhaust path 21 is connected to a common exhauster 23 through an exhaust pipe 22. The exhaust path 21 is opened or closed by a valve device 3 provided inside thereof.

As illustrated in FIG. 2, an exhaust space 20 is formed at the sidewall 111 of the processing container 11 to communicate with the processing space 10, which is created by the gas supplier 13 at the processing position and the stage 12, through the gap 16. As illustrated in FIG. 3, the exhaust space 20 is formed to extend toward an outer rim of the processing container 11 while narrowing in width in a plan view toward the outer rim, thus having an approximately triangular shape. The above-described exhaust port 2 opens at a top of this triangle spaced apart from both the stage 12 and the gas supplier 13.

Although the gap 16 is formed around an entire circumference of the stage 12 as described above, each portion of the gap 16 faces one of eight exhaust spaces 20. In other words, the exhaust spaces 20 are provided to allow for exhaust around an entire circumference of the gap 16. As illustrated in FIG. 2, an upper end of each exhaust space 20 is positioned above a lower surface of the perimeter area 152 of the gas supplier 13 at the processing position, and a lower end of the exhaust space 20 is positioned below the upper surface of the stage 12. This formation of the exhaust space 20 prevents interference with detection of a lower surface height of the perimeter area 152 of the gas supplier 13 and an upper surface height of the stage 12, which is described in detail later, and further, detection of the size of the gap 16 obtained from these heights.

### <Valve Device>

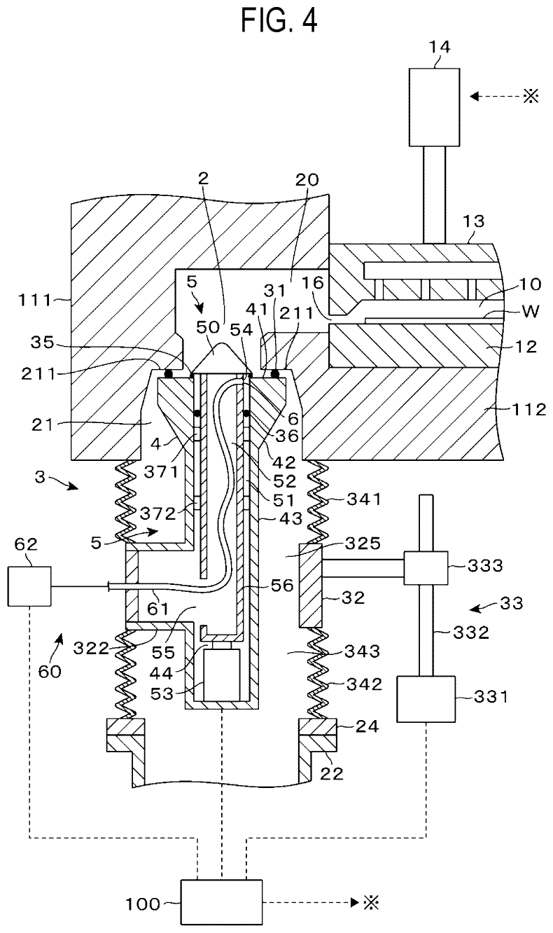

Next, the valve device 3 is described with reference to FIGS. 4 to 8. The valve device 3 in this example is an automatic pressure control (APC) valve, and is configured to receive a control signal from a controller 100, which is described later, to change an opening degree thereof, thereby adjusting an internal pressure of the processing container 11 according to the opening degree. The valve device 3 is provided for each exhaust path 21, and includes a valve body 5, which includes a valve main body 4 and a mover 51 that moves up and down relative to the valve main body 4, as well as a detector 60 for detecting the height of each component mentioned above.

The valve main body 4 of the valve device 3 is configured to open or close the exhaust path 21. As illustrated in FIG. 4, the exhaust path 21 has a larger diameter than the exhaust port 2, and a connection portion between the exhaust port 2 and the exhaust path 21 expands in diameter to form an annular stepped portion 211. Furthermore, an upper side of the exhaust path 21 expands in diameter from the stepped portion 211 downward, and a lower end of the exhaust path 21 opens at the bottom wall 112 of the processing container 11.

An upper surface of the valve main body 4 is formed as an annular planar portion 41, and at a position where the exhaust path 21 is blocked as illustrated in FIG. 4, the planar portion 41 is connected to the stepped portion 211, formed by the exhaust port 2 and the exhaust path 21, via a first seal member 31. The first seal member 31 includes, for example, an O-ring. Although illustrated in a simplified manner in the drawing, a groove is formed in one of the processing container 11 and the valve main body 4, and the O-ring is positioned in this groove. Then, when blocking the exhaust path 21, restoring force of the O-ring is used to ensure an airtight seal between the processing container 11 and the valve main body 4.

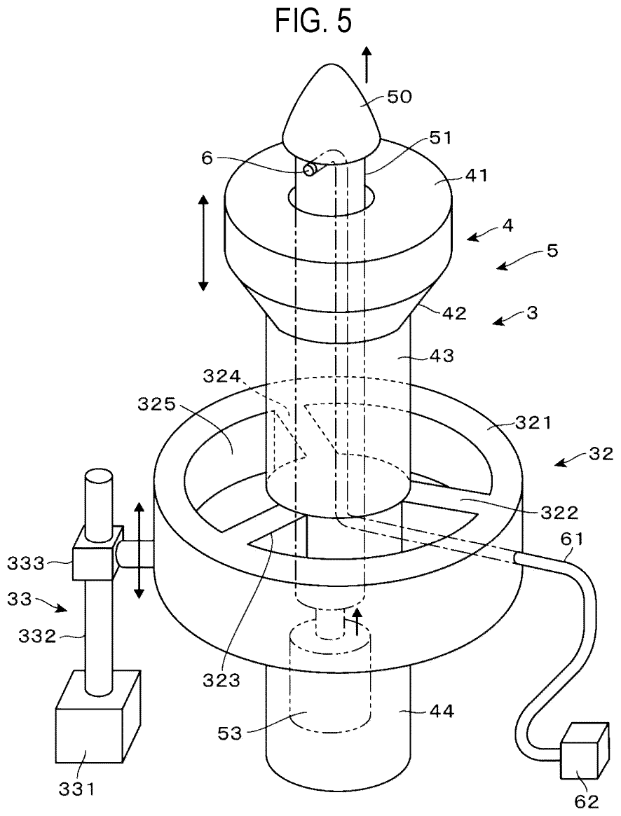

The valve main body 4 includes an inclined portion 42 that tapers downward below the planar portion 41, and a cylindrical portion 43 that extends vertically below the inclined portion 42. As illustrated in FIGS. 4 and 5, the cylindrical portion 43 is supported laterally at an intermediate position in its extending direction by a support member 32 below the processing container 11, and is connected to a first driver 33 via the support member 32. The support member 32 includes an annular member 321 formed concentrically with the valve main body 4 and a plurality of, for example, three, connecting members 322, 323 and 324 connecting the valve main body 4 to the annular member 321. These connecting members 322 to 324 are positioned, for example, to equally divide the annular member 321 in a circumferential direction, and an interior of one connecting member 322 is formed as a storage space for a detection part 6 to be described later.

As illustrated in FIG. 4, a first bellows 341 is provided between an upper surface of the support member 32 and the bottom wall 112 of the processing container 11, and a second bellows 342 is provided between a lower surface of the support member 32 and the exhaust pipe 22, with a connecting member 24 interposed between the exhaust pipe 22 and the second bellows 342. In this way, the exhaust path 21 is connected to the exhaust pipe 22 through an exhaust area 343, which is surrounded by both the first bellows 341 and the second bellows 342. As illustrated in FIG. 5, an opening 325 is formed between the annular member 321 and each of the connecting members 322 to 324 in the support member 32, allowing the gas to flow downward in the exhaust area 343 through the opening 325.

The first driver 33 is formed as, for example, a ball screw mechanism, and is configured such that a lifting member 333 connected to the support member 32 moves up and down when a motor 331 rotates a ball screw 332. For example, the motor 331 includes an encoder, and position data of the encoder is output to the controller 100.

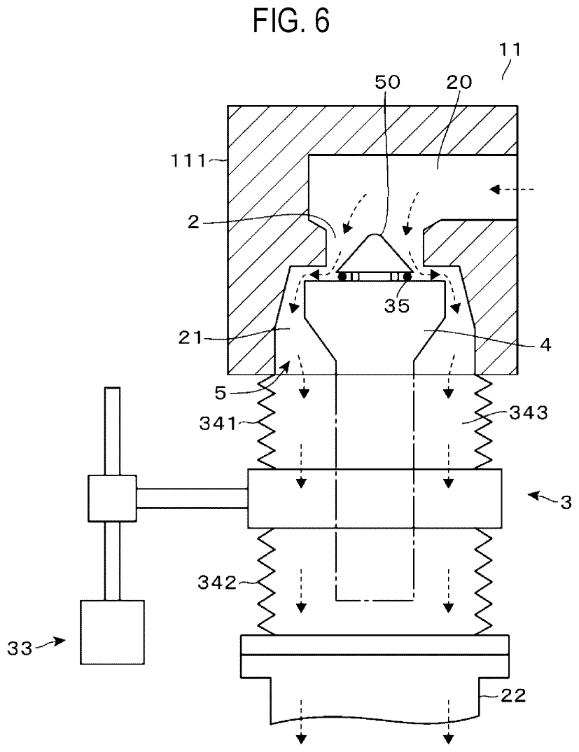

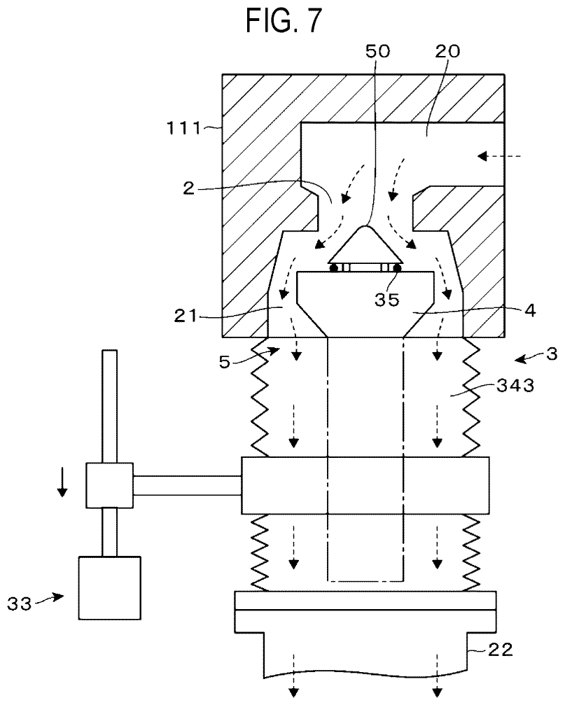

In this way, the valve main body 4 is configured to be stoppable by the first driver 33 between a position where it closes the exhaust path 21 (position illustrated in FIG. 4) and a plurality of positions where it opens the exhaust path 21 (for example, positions illustrated in FIGS. 6 and 7). In further detail, the valve main body 4 does not stop only at two positions, i.e., the positions for opening and closing the exhaust path 21 (i.e., simply opening and closing the exhaust path 21) but may stop at any height position where it opens the exhaust path 21.

In addition, when the exhaust path 21 is open, the lower the valve main body 4 is positioned, the wider the annular space between an upper end of the valve main body 4 and an inner circumferential surface of the exhaust path 21 (the opening degree of the exhaust path 21 increases), which increases an exhaust flow rate by the exhauster 23, reducing the internal pressure of the processing container 11. As described above, the valve main body 4 may stop at any height position (open position) where it opens the exhaust path 21 to regulate the pressure in the interior (the exhaust space 20 and the processing space 10) of the processing container 11 according to the height position thereof. The internal pressure of the processing container 11 is changed by changing the height position of the valve main body 4.

In the valve device 3, the correlation between the open position of the valve main body 4 and the internal pressure of the processing container 11 is pre-established, and the open position of the valve main body 4 is set based on a set internal pressure of the processing container 11.

For a gas flow by exhaust as indicated by the dashed arrows in FIGS. 6 and 7, the gas flows from the exhaust space 20 toward the exhaust path 21 through the exhaust port 2, and then from the exhaust area 343 inside the first bellows 341 and second bellows 342 toward the exhaust pipe 22. In addition, when stopping exhaust inside the processing container 11, the exhaust path 21 is closed by the valve main body 4, as illustrated in FIG. 4. This causes the first seal member 31 to come into close contact with the stepped portion 211, thereby sealing the exhaust path 21 and blocking the gas flow.

A first storage space 44 is formed to extend vertically in an interior of the valve main body 4. For example, the first storage space 44 is formed as an elongated circular recess in a plan view, and the mover 51 is provided in an interior of the first storage space 44. In this example, the mover 51 forms a second storage space 52 partitioned from the first storage space 44 and includes, for example, a main body 56 formed as a bottomed elongated cylinder.

A cap 50 is provided on the main body 56 to cover the second storage space 52 from above. When viewed in a plan view, the cap 50 is formed to be smaller than the exhaust port 2 but larger than the main body 56 and the first storage space 44 of the valve main body 4. As illustrated in FIGS. 4 and 5, the cap 50 is formed, for example, in an approximately conical shape with a rounded top, and has a flat lower surface. This shape helps to reduce resistance of the cap 50 to the gas flowing from an upper side of the cap 50, and to guide the gas flow by an inclined surface, which is formed to expand in diameter from the top downward, thus minimizing gas retention and allowing the gas to flow quickly into the exhaust path 21.

A second driver 53 is provided in the first storage space 44 to move the mover 51, and for example, an air cylinder is used as the second driver 53. The second driver 53 is positioned below the main body 56 and is configured to push up a bottom of the main body 56 and move the mover 51 vertically between a lowered position and a raised position above the valve main body 4. As such, the first storage space 44 forms a movement path for the mover 51, and the valve body 5 extends or contracts by movement of the mover 51 between the lowered position and the raised position relative to the valve main body 4. Then, the above-described first driver 33 raises or lowers not only the valve main body 4 but also the second driver 53 and the mover 51, both of which are supported by the valve main body 4. In addition, the second driver 53 is connected to an external power supply via the hollow connecting member 322.

When processing the wafer W, the mover 51 is at the lowered position and the valve body 5 is in the contracted state. As illustrated in FIG. 4, when the mover 51 is at the lowered position, the main body 56 is inside the first storage space 44 in the exhaust path 21, and the top (cap 50) of the mover 51 is positioned below an upper end of the exhaust port 2. When the mover 51 is at such lowered position, the cap 50 does not protrude upward from the exhaust port 2, thus allowing the gas to flow quickly into the exhaust path 21 without impeding the gas flow. In addition, although the valve main body 4 is set to the open position where it opens the exhaust path 21 until a specified vacuum pressure is achieved before processing, the valve main body 4 may be positioned to close the exhaust path 21 to increase the pressure if a reaction pressure is high when processing the wafer W. In addition, when the exhaust path 21 is closed by the valve main body 4, it is desirable to set the pressure corresponding to a vacuum region even if there is some amount of gas present.

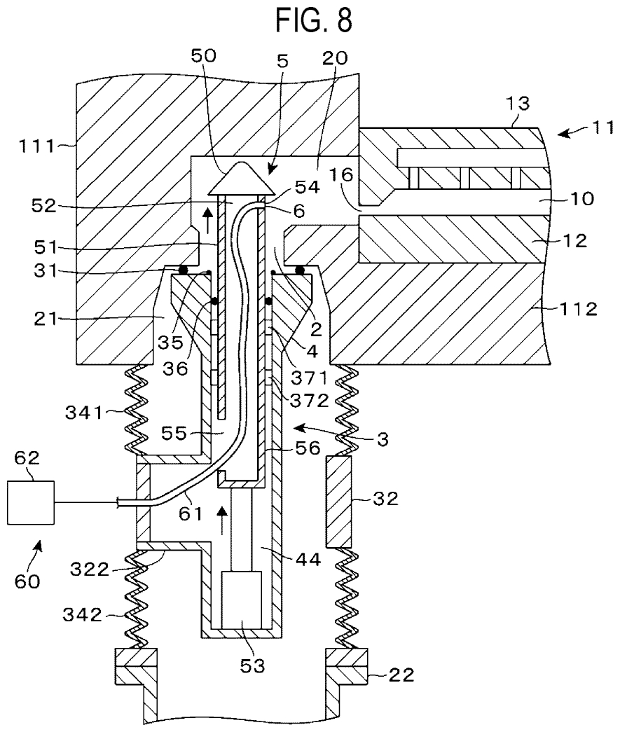

When the detection part 6 detects the internal state of the processing container 11 as described later, the mover 51 is at the raised position and the valve body 5 is in the extended state. As illustrated in FIG. 8, when the mover 51 is at the raised position, the cap 50 protrudes from the exhaust port 2 and is located in the exhaust space 20. Accordingly, if an interior of the exhaust path 21 is assumed as a first position and an interior of the exhaust space 20 is assumed as a second position, the mover 51 is located at the second position during detection, which is at an exhaust upstream compared to the first position where it is located when processing the wafer W.

Next, the detector 60 is described. The detector 60 is an optical fiber sensor and includes a fiber bundle 61 in which a light emitting optical fiber and a light receiving optical fiber are combined together, and a detection unit 62. The fiber bundle 61 is flexible and is connected at its base to the detection unit 62. In addition, the light emitting optical fiber and the light receiving optical fiber are not distinguished in the drawing.

Light from a light source included in the detection unit 62 is emitted through the light emitting fiber onto a detection target from a tip of the light emitting fiber. Then, when light reflected from the detection target reaches a tip of the light receiving fiber, the reflected light enters a light receiving element included in the detection unit 62 through the light receiving fiber. The light receiving element sends a detection signal to the controller 100 to be described later upon receiving the light, enabling the detection of the detection target. The detector 60 as described above is configured as a reflective photoelectric sensor. In addition, the detection target includes the stage 12 and the gas supplier 13, and as to be described in detail later, a height of the gap 16 formed between the stage 12 and the gas supplier 13 is measured by detecting the height position of these respective members.

An opening 54 is formed at a sidewall upper portion of the main body 56 of the mover 51 to provide communication between the second storage space 52 inside the mover 51 and an outside of the mover 51. A tip of the fiber bundle 61 constituting the detection part 6 is positioned at the opening 54 and is disposed to enable horizontal light emission toward a center of the processing container 11 in a plan view.

A vertically elongated opening 55 is formed at a lower portion of the main body 56 to overlap in position with the hollow connecting member 322 of the support member 32 as viewed in an extending direction of the connecting member 322. To describe in more detail, when the mover 51 is at the lowered position, an entire height of the opening 55 overlaps with the space formed by the connecting member 322, and when the mover 51 is at the raised position, only a lower side of the opening 55 overlaps with the space formed by the connecting member 322.

The fiber bundle 61 is disposed to extend downward from the opening 54 through the second storage space 52, with the base thereof drawn outside the support member 32 through the connecting member 322 from the opening 55 and connected to the detection unit 62. In addition, the aforementioned detection part 6 corresponds to a tip portion of the fiber bundle 61 that performs light emission and light reception. The tip portion of the fiber bundle 61 includes the tip of the fiber bundle 61 positioned at the opening 54 as well as a portion of the fiber bundle 61 located inside the second storage space 52.

As described above, the fiber bundle 61 is provided in the mover 51, so that the detection part 6, which forms the tip portion of the fiber bundle 61, moves up and down along with the mover 51. The second storage space 52, which is formed by the mover 51 and stores the detection part 6, may serve as a space to isolate and protect the detection part 6 from each gas flowing outside the valve body 5. When the mover 51 is at the lowered position, the opening 54 where the tip of the fiber bundle 61 constituting the detection part 6 is positioned is located inside the first storage space 44. In this lowered position state, a second seal member 35, which is described later, seals a gap between an outer circumferential surface of the mover 51 and an inner circumferential surface of the valve main body 4, preventing the process gas used for processing the wafer W from adhering to the tip of the fiber bundle 61 through the opening 54.

Then, when the mover 51 is at the raised position, the opening 54 is positioned above the first storage space 44. More specifically, by positioning the opening 54 at the exhaust space 20, optical detection as described above may be performed during the vertical movement of the valve body 5 by the first driver 33. Hereinafter, when referring to a height position of the detection part 6 while the mover 51 is at the raised or lowered position, it may also be stated as the detection part 6 being at the raised or lowered position.

Further, the second seal member 35 is provided on a top of the valve main body 4 to surround an opening of the first storage space 44 and comes into close contact with a lower surface perimeter of the cap 50 of the mover 51, which is at the lowered position. Therefore, when the mover 51 is at the lowered position, the gap formed between the mover 51 and the valve main body 4 is sealed as described above. Furthermore, a third seal member 36 is provided between the second storage space 52 and the first storage space 44 of the valve main body 4, and, for example, sliding bearing members 371 and 372 are provided at two upper and lower positions. These second seal member 35 and third seal members 36 are configured in the same way as the first seal member 31.

In this way, the mover 51 is configured to move quickly between the lowered position and the raised position inside the first storage space 44 by the second driver 53 while ensuring airtightness. The third seal member 36 is positioned below the opening 54 of the mover 51, which is at the raised position, and is provided to separate the atmospheric atmosphere from the vacuum atmosphere. In addition, for the convenience of illustration, the first to third seal members 31, 35 and 36 and the sliding bearing members 371 and 372 may be omitted from the drawings.

The substrate processing apparatus 1 having the above-described configuration includes the controller 100 as illustrated in FIG. 1. The controller 100 is configured with a computer including a storage storing a program, a memory, and a CPU. The program is configured to output controls necessary for performing the processing of the wafer W or control signals to control the processing of the wafer W as necessary based on detection results from the detector 60, which is described later, from the controller 100 to each component of the substrate processing apparatus 1.

Such a program is stored in the storage of the computer, such as a computer readable flexible disk, compact disk, hard disk, magneto-optical (MO) disk, or non-volatile memory, and is installed in the controller 100 after being read from the storage.

A brief description of the processing of the wafer W performed by the substrate processing apparatus 1 is provided. First, with the gas supplier 13 located at the transfer position, the wafer W is loaded into the processing container 11 through the transfer port 113 and is placed on the stage 12. Subsequently, the gas supplier 13 is lowered to the processing position, the interior of the processing container 11 is set to a preset pressure, and the wafer W on the stage 12 is heated to a set processing temperature between 400 degrees C. and 800 degrees C. by the heater 121. Then, the raw material gas and the reactant gas are alternately supplied in the order of raw material gas→replacement gas→reactant gas→replacement gas from the gas supplier 13 into the processing space 10, forming a thin film on the wafer W by ALD.

At this time, the interior of the processing container 11 is exhausted by the exhauster 23 via the valve device 3, and is adjusted to a preset pressure range by controlling the opening degree of the valve device 3. In other words, the valve body 5 of the valve device 3 is positioned at a height depending on a set internal pressure of the processing container 11. The process gas and replacement gas supplied into the processing space 10 flows from the gap 16, which is formed at the lateral side of the stage 12 to surround the stage 12, toward the exhaust port 2. Then, these gases are guided by the cap 50 forming the top of the valve body 5 to flow toward an outside of the valve main body 4, thus being exhausted through the exhaust path 21.

By the way, in the substrate processing apparatus 1, the exhaust path 21 is disposed at equally spaced positions in the circumferential direction at the lateral side of the processing space 10 to equalize an exhaust volume inside the processing space 10 along the circumferential direction, thereby improving in-plane uniformity of processing for the wafer W. At this time, since the exhaust volume from the processing space 10 to the exhaust space 20 varies depending on the size (height) of the gap 16 between the gas supplier 13 and the stage 12, it is important to maintain a consistent size of the gap 16 along the circumferential direction. Further, retention of the gas inside the processing space 10 varies depending on the size of the gap 16, making it necessary to manage the size of the gap 16 in order to achieve a desired amount of processing (in this case, film formation amount) for the wafer W. However, the gap 16 may deviate from a preset size due to thermal expansion of the stage 12 or the gas supplier 13 resulting from a relatively high processing temperature of the wafer W as well as changes over time.

For this reason, detecting the size of the gap 16 is required, but this detection is challenging when an internal temperature of the processing container 11 is high. For example, a method using a pressure detection sheet fitted into the gap 16 to measure the size of the gap 16 confronts issues with heat resistance of the sheet. Further, although a method using a sensor to check the gap 16 from the atmosphere by providing a window on the processing container 11 may also be considered, this method has issues of verification being impossible due to deposits attached to the window and deterioration in temperature uniformity inside the processing container 11 due to material differences of the processing container 11, which may adversely affect the processing.

Therefore, in the present disclosure, the detector 60 is provided in the valve device 3 of the processing container 11 and is configured to enable detection of the internal state of the processing container 11.

Next, detection of the state of the processing container 11 by the valve device 3 is described. Although the detection of state of the processing container 11 is performed, for example, during startup or regular maintenance of the apparatus, a case where detection is performed while the stage 12 is heated after performing film formation on a predetermined number of wafers W in the substrate processing apparatus 1 is described herein by way of example.

In this example, the internal state of the processing container 11 detected by the detector 60 is the distance between the gas supplier 13 (upper structure) and the stage 12, i.e., the size of the gap 16. As already described, the size of the gap 16 is defined as the distance between the lower surface of the perimeter area 152 of the gas supplier 13, which is at the processing position, and the upper surface of the stage 12, but may also be described as the distance between the gas supplier 13 and the stage 12.

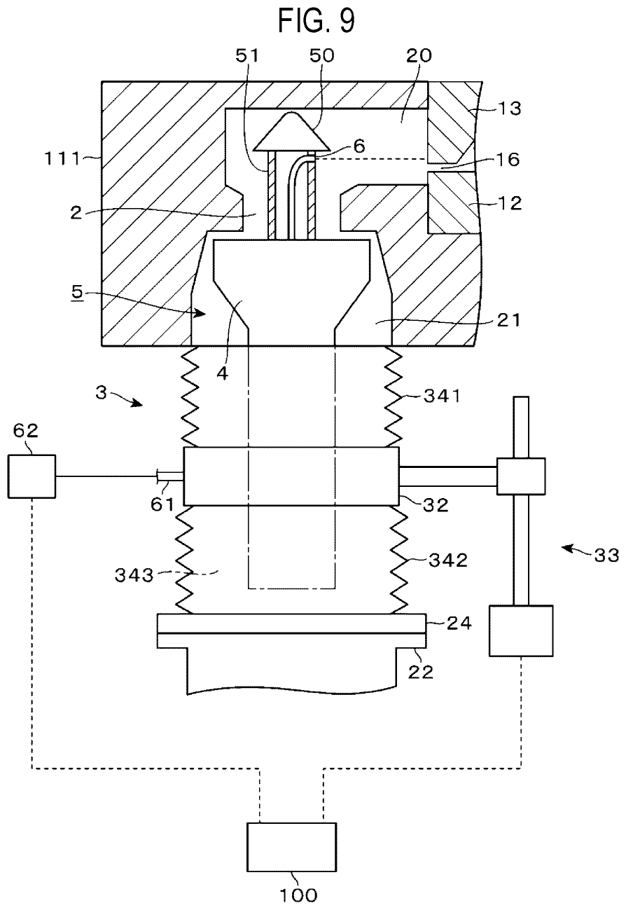

Then, when performing detection by the detector 60, the gas supplier 13 remains at the processing position, and as illustrated in FIG. 9, the valve body 5 is located at a height position (detection start position) where it temporarily closes the exhaust path 21, and the mover 51 is raised to the second position by the second driver 53. Thus, the tip of the fiber bundle 61 constituting the detection part 6 is positioned at a height above the lower end (the lower surface of the perimeter area 152) of the gas supplier 13, which is at the processing position. In addition, the detection by the detection part 6 may be performed while continuing the exhaust by the exhauster 23, or may be performed while the exhaust is stopped, based on timing of performing the detection, but herein, the exhaust is described to continue.

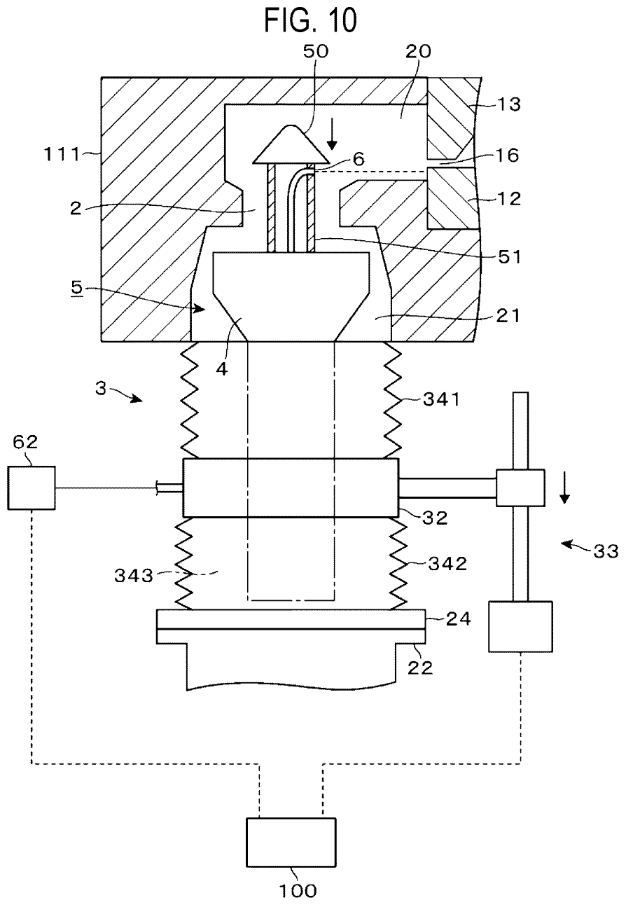

Next, detection by the detection part 6 starts. This detection is performed by lowering the valve body 5 by the first driver 33 while light from the light source is emitted laterally from the detection part 6, with reflected light from the gas supplier 13 or the stage 12 being received by the detection part 6. The motor 331 lowers the valve body 5 (i.e., increases the opening degree of the valve), and the detection is performed by scanning. In this way, once the valve body 5 is lowered to a detection stop position at a predetermined height as illustrated in FIG. 10, the lowering is stopped and the light emission is stopped. As illustrated in FIG. 10, the detection stop position is a position where the tip of the fiber bundle 61 constituting the detection part 6 is positioned at a height below the upper surface of the stage 12.

In this way, by scanning the valve body 5 from the detection start position to the detection stop position, the light emitted laterally from the detection part 6 is reflected by a sidewall of the gas supplier 13 or a sidewall of the stage 12 at a height position above or below the gap 16, and is therefore received by the light receiving element of the detection unit 62. On the other hand, the light emitted from the detection part 6 may not be received by the light receiving element at a height position where the gap 16 is formed.

As a result, the detection unit 62 acquires light reception/non-reception data, which is output to the controller 100. Further, the height position of the valve body 5 is acquired as height position data by the encoder provided in the motor 331 of the first driver 33 and is output to the controller 100.

The controller 100 includes a program that associates the light reception/non-reception data with the height position data and calculates the height position where the gap 16 is formed, i.e., the distance between the gas supplier 13 (upper structure) and the stage 12. In this way, the controller 100 acquires the distance between the gas supplier 13 and the stage 12 (the size of the gap 16) as an example of the internal state of the processing container 11 based on the detection results from the detector 60.

Through the operation of each valve device 3, as described above, the size of each circumferential portion of the gap 16, which is connected to the processing space 10 and is formed into an annular shape, may be acquired. If there is a variation in the size of each portion of the gap 16, the flow rate of the gas flowing through each circumferential portion in the plane of the wafer W during the processing of the wafer W may differ, potentially leading to variation in processing states across each portion. Therefore, if the size of the gap 16 detected in any valve device 3 deviates from an allowable range or if there is a significant variation in the size of each portion of the gap 16, the user needs to temporarily stop the operation of the apparatus to perform maintenance on each component of the apparatus so that the size of the gap 16 falls within a normal range.

By the way, the substrate processing apparatus 1 is provided with three or more valve devices 3, which advantageously enables acquisition of an inclination of each of the gas supplier 13 and the stage 12 with respect to a horizontal plane, in addition to the size of the gap 16.

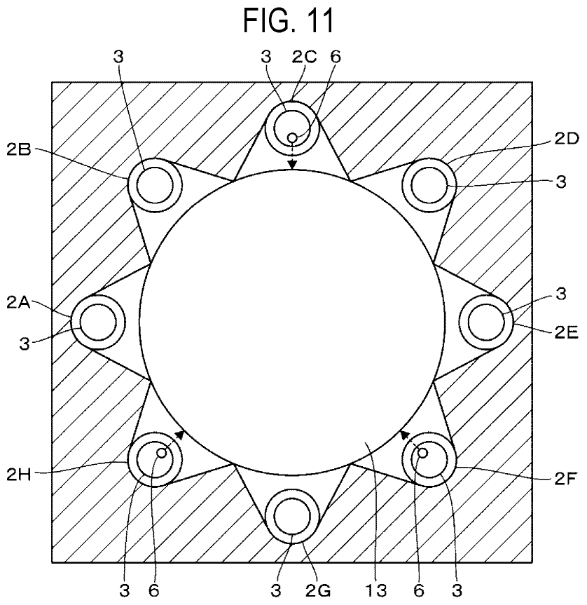

To specifically describe the inclination acquisition procedure, the same detection operation as described above for the size of the gap 16 is performed using three or more valve devices 3. In FIG. 11, an example is illustrated in which the detection operation is performed by the valve devices 3 provided in exhaust ports 2C, 2F and 2H while assuming there are eight exhaust ports 2 designated as exhaust ports 2A to 2H. Then, the controller 100 may acquire a lower surface height of the perimeter area 152 of the gas supplier 13 and an upper surface height of the stage 12 from the light reception/non-reception data acquired by the operation of the valve devices 3 and the height position data from the encoder of the motor 331.

The controller 100 assumes that three locations, where the height of the gas supplier 13 is acquired, are positioned on the same plane, and calculates an inclination of this plane as the inclination of the gas supplier 13. Similarly, the controller 100 assumes that three locations, where the height of the stage 12 is acquired, are positioned on the same plane, and calculates the inclination of this plane as the inclination of the gas supplier 13.

By determining whether these inclinations are within a preset allowable range, maintenance on the apparatus may be performed if any is out of the allowable range. In addition, although an example is illustrated in which only three valve devices 3 are used to detect the respective inclinations, detection may be performed using more valve devices 3. In that case, different combinations of three valve devices 3 may be used for inclination calculation, and calculations, such as taking an average of multiple types of inclinations, may be performed to improve accuracy of the calculated inclination.

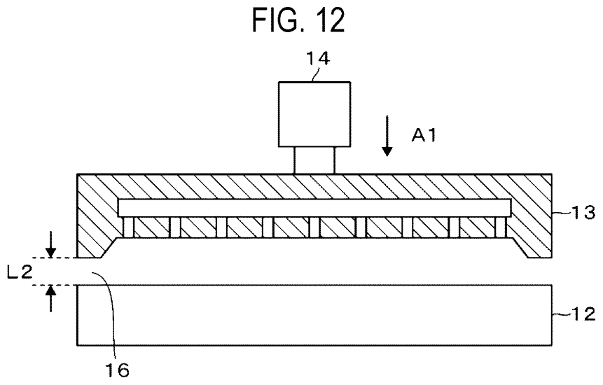

Further, in a case where both the gap 16 and the respective inclinations are detected, it is conceivable that the inclinations are within an allowable range, but the gap 16 exceeds an allowable range. In such a case, control is applied as follows. For example, as illustrated in FIG. 12, it is assumed that the allowable range for the gap 16 is L1 mm, and the detected value (average value) of the gap 16 is L2 mm, with L2>L1.

At this time, for example, it is assumed that the gas supplier 13 is set to descend by A1 mm from the transfer position (see FIG. 1) to the processing position. At this time, the controller 100 changes the descent distance to (A1+(L2−L1)) mm, and outputs a command to the lift 14, which serves as a distance changer, to move according to the changed setting value.

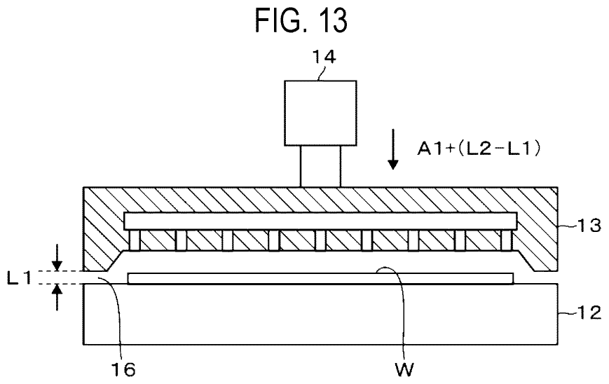

In this way, for the wafer W processed after the detection of the gap 16 and the respective inclinations, as illustrated in FIG. 13, the gas supplier 13 is lowered by the changed distance to adjust the distance between the gas supplier 13 and the stage 12 when supplying the process gas into the processing container 11, and thereafter, the wafer W is processed as usual. FIG. 13 illustrates a state where the descent distance of the gas supplier 13 has been changed to (A1+(L2−L1)) mm, resulting in the average size of the gap 16 of L1 mm.

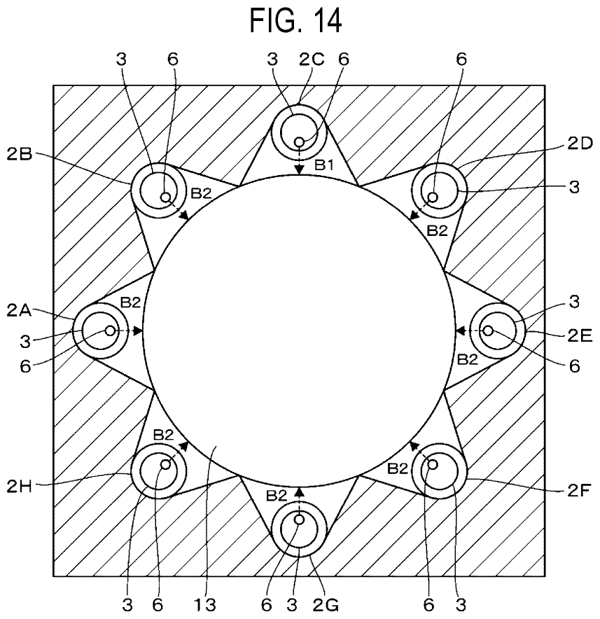

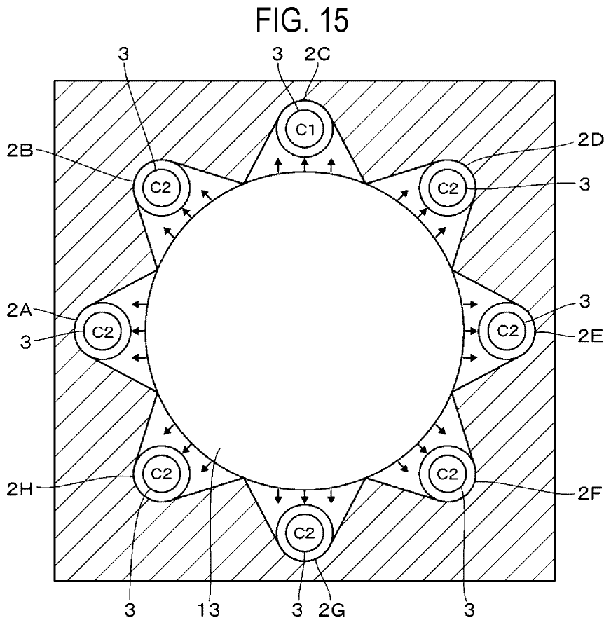

Another handling example after the detection of the gap 16 is described with reference to FIGS. 14 and 15. In this example, the distance between the gas supplier 13 and the stage 12 is detected as the internal state of the processing container 11, and based on the detection results, the controller 100 outputs a control signal to the first driver 33 of the valve body 5 to change settings for the opening degree of the valve device 3, in order to control the processing of the wafer W.

Specifically, as illustrated in FIG. 14, for example, the size of the gap 16 is acquired by the detection part 6 provided in all of the exhaust ports 2A to 2H, as already described. Herein, it is assumed that a preset size of the gap 16 is B2 mm, and a preset height of each valve body 5 required to maintain a predetermined internal pressure of the processing container 11 is C2.

Then, FIG. 14 illustrates an example in which the detection results of the gap 16 by the detection part 6 provided in the eight exhaust ports 2A to 2H is B1 mm at the exhaust port 2C and B2 mm at the other exhaust ports 2A, 2B and 2D to 2H, where B1<B2.

Herein, the larger the gap 16 between the gas supplier 13 and the stage 12, the greater the exhaust volume. Accordingly, for example, if exhaust is uniformly performed from each exhaust port 2, an exhaust volume from a region of the gap 16 connected to the exhaust port 2C, where the size of the gap 16 is B1 mm, becomes smaller than that from the other regions connected to the other exhaust ports 2 where the gap size is B2 mm. Therefore, in the valve device 3 of the exhaust port 2C, the height of the valve body 5 is set to a lower height C1 than the height C2 of the valve body 5 of the other valve device 3 to process the wafer W. In other words, for the valve device 3 of the exhaust port 2C, the opening degree thereof needs to be increased more than that of the valve bodies 5 of the other valve devices 3 so that the small exhaust volume due to the small gap 16 connected to the exhaust port 2C is compensated (see FIG. 15). This increases uniformity of the exhaust volume across the entire circumferential direction of the gap 16, thereby enhancing uniformity of the processing within the plane of the wafer W.

In addition, the correlation between the deviation from the set value B2 mm for the gap and the amount by which the valve body 5 is set to deviate from the height C2 is stored in advance in the controller 100, and the height C1 of the valve body 5 described above is obtained by offsetting the amount derived from the correlation from the height C2. Although the description addresses a case where the detected size of the gap 16 is smaller than the set value, if the detected size is larger than the set value, the opening degree of the valve device 3 that detected such a larger value may be reduced according to the correlation stored in the controller 100. In this way, by setting and changing the opening degree of the valve device 3 according to the size of the gap 16 at each detected position, exhaust volume uniformity in the circumferential direction of the processing space 10 may be controlled.

By the way, in the above-described example, detection is performed by raising the mover 51 to the second position via the second driver 53 while allowing the detection part 6 to scan by the motor 331.

However, if light from the detection part 6 is emitted over a wide range and the gap 16 is included in the light emission range, there is no need for the detection part 6 to scan. As already described, reflected light is not received at the height position where the gap 16 exists, and therefore, an amount of reflected light varies according to the size of the gap 16. Therefore, for example, the size of the gap 16 may be detected by the amount of reflected light by determining the correlation between the amount of reflected light and the size of the gap 16 in advance.

As described above, according to the present disclosure, in the processing apparatus including the processing container 11 for processing the wafer W, it is possible to detect the internal state of the processing container 11 by the detection part 6 provided in the valve device 3 that opens or closes the exhaust path 21 connected into the processing container 11. Accordingly, there is no need to separately install the detection part 6 apart from the valve device 3 to detect the internal state of the processing container 11, thereby preventing the processing apparatus 1 from becoming larger or more complex. Further, scanning of the detection part 6 is performed using the first driver 33, which serves to change the opening degree of the valve device 3, so that there is no need to provide a new lifting mechanism, allowing for a simpler configuration when equipping the detection part 6.

Furthermore, since the mover 51 that accommodates the detection part 6 only moves to the exhaust space 20 outside the exhaust port 2 when detecting the internal state of the processing container 11 as already described, this prevents interference with the gas flow from the processing space 10 to the exhaust space 20 during the processing of the wafer W. Accordingly, there is no risk of interference with the processing of the wafer W when performing the optical detection of the internal state of the processing container 11 as described above.

Further, with the above-described shape of the top (cap 50) of the valve body 5, the retention of the process gas around the valve body 5 is prevented during the processing of the wafer W, and components constituting the process gas are prevented from adhering to the valve body 5. Even if adhesion of such gas components occurs and adhered matters (foreign matters) detaches from the valve body 5 due to the upward movement of the mover 51 when performing the detection, the detached matters flow downward through the exhaust path 21 and are removed since the valve body 5 is provided at the exhaust path 21. In other words, this configuration of the valve device 3 allows for the detection of the internal state of the processing container 11 while letting the foreign matters (particles) derived from the process gas be removed to outside the exhaust port 2 and preventing them from affecting the processing of the wafer W.

By the way, for the convenience of description, the perimeter area 152 of the gas supplier 13 defining the gap 16 is described as partitioning the space in which the wafer W is stored, designating the space inside the perimeter area 152 as the processing space 10 where the wafer W is processed and the space outside the gap 16 as the exhaust space 20. However, since the processing space 10 and the exhaust space 20 communicate with each other through the gap 16, the processing space 10, the exhaust space 20, and the gap 16 may be considered as a single processing space for processing the wafer W. Accordingly, the mover 51 may be said to be located in the exhaust path during detection by the detection part 6, as well as in the processing space for the wafer W.

Moreover, the fiber bundle 61 that constitutes the detection part 6 may use a material with relatively high heat resistance, such as quartz glass, to make it less susceptible to radiant heat from the heated high temperature stage 12. Further, since the base of the fiber bundle 61 is connected to the detection unit 62 outside the valve device 3 and the light source or the light receiving element is spaced apart from the processing container 11, they are less affected by the heat inside the processing container 11. Therefore, the configuration of the valve device 3 prevents adverse effects of heat on the light source or the light receiving element, also enabling high-accuracy detection. By equipping the substrate processing apparatus 1 with the valve device 3 in such way, the height detection of each component described above is carried out even when the stage 12 is heated. Therefore, for example, if a processing defect occurs with the wafer W, a relationship between the defect and the size of the gap 16 followed by the thermal expansion of the stage 12 and the gas supplier 13 may be identified, facilitating investigation into the cause and countermeasures.

In addition, the substrate processing apparatus 1 of the present disclosure is configured such that optical height detection for each of the gas supplier 13 and the stage 12 is performed laterally by the detection part 6. For example, compared to a configuration in which a reflective distance sensor installed at an arbitrary position of the processing container 11 emits light vertically toward each of the gas supplier 13 and the stage 12 and detects the height of each by receiving reflected light, the above configuration allows for more precise height detection of these components. Therefore, the size of the gap 16 may also be accurately acquired.

### Second Embodiment

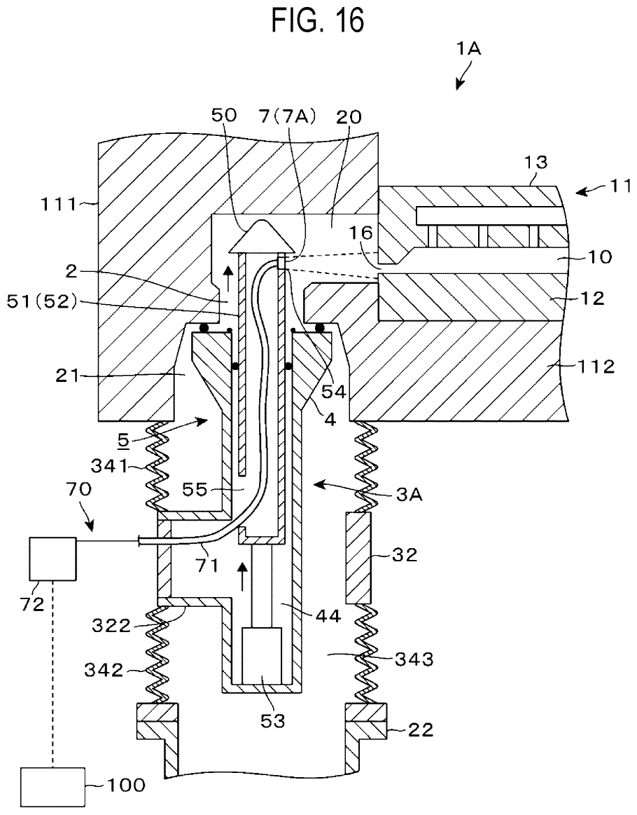

Next, a second embodiment of the present disclosure is described with reference to FIG. 16. A valve device 3A of this embodiment includes a detector 70 instead of the detector 60. The detector 70 includes a main body 7A including a CCD camera (hereinafter referred to as “camera”) and a lighting and a detection unit 72, and the main body 7A and the detection unit 72 are connected by a flexible cable 71. The main body 7A is located at the opening 54 of the mover 51, and the cable 71 is routed through the mover 51 and the valve main body 4, similarly to the fiber bundle 61, so that the base thereof is connected to the detection unit 72, which is located in the atmospheric atmosphere. Through the wiring in the cable 71, power is transmitted from the detection unit 72 to the lighting of the main body 7A, and image data is transmitted from the camera of the main body 7A to the detection unit 72.

The detection unit 72 includes, for example, a display for displaying the image data captured by the camera, and is configured to output the image data to the controller 100. In the drawing, a portion including the main body 7A and corresponding to the detection part 6 of the detector 60, is illustrated as a detection part 7.

The lighting emits light toward the center of the processing container 11. Then, a field of view of the camera is also oriented toward the center of the processing container 11 so as to capture images of an area toward which the light is emitted. In the drawing, an imaging area of the camera is outlined with a dotted line. Aside from these differences, the second embodiment is configured similarly to the first embodiment described above, and the same reference numerals are given to the same components, and further descriptions are omitted.

In this example, the raised position of the mover 51 is set to a height position where the camera is able to capture images of an area including the gap 16. Then, when the mover 51 is raised to the second position, the internal state of the processing container 11 is detected by imaging using the detection part 7 without the need for the detection part 7 to scan. In other words, in this example, the internal state of the processing container 11 is detected when the detection part 7 is at the second position, with the exhaust path 21 closed.

The detected image data is output to the controller 100 via the detection unit 72, and image processing based on this image data enables determination of the size of the gap 16, i.e., the height position of the lower end of the gas supplier 13 and the height position of the upper end of the stage 12. Further, the operator may also inspect the size of the gap 16 based on the image data displayed on the display of the detection unit 72 and input detection results thereof into the controller 100.

Then, control on the processing of the wafer W as described in FIGS. 12 to 15 may also be performed by the controller 100 based on the detection results of the detection part 7 in the same manner as in the first embodiment.

In addition, if the imaging area of the camera is narrow, the internal state of the processing container 11 is detected by the mover 51 performing scanning from the second position (a height position where the camera captures images of an upper side of the gap 16) to a height position where the camera captures images of a lower side of the gap 16. In this example as well, it is possible to detect the internal state of the processing container 11 by the detection part 7 provided in the valve device 3A, achieving the same effects as in the first embodiment.

The detector 70 may be configured as a so-called fiberscope. Specifically, the cable 71 includes multiple optical fibers, in addition to the wiring, and the portion referred to as the main body 7A includes a lens and the above-described lighting. Light that passes through the lens and enters the optical fibers may be transmitted to the detection unit 72 through these optical fibers, enabling the detection unit 72 to capture images of the gap 16.

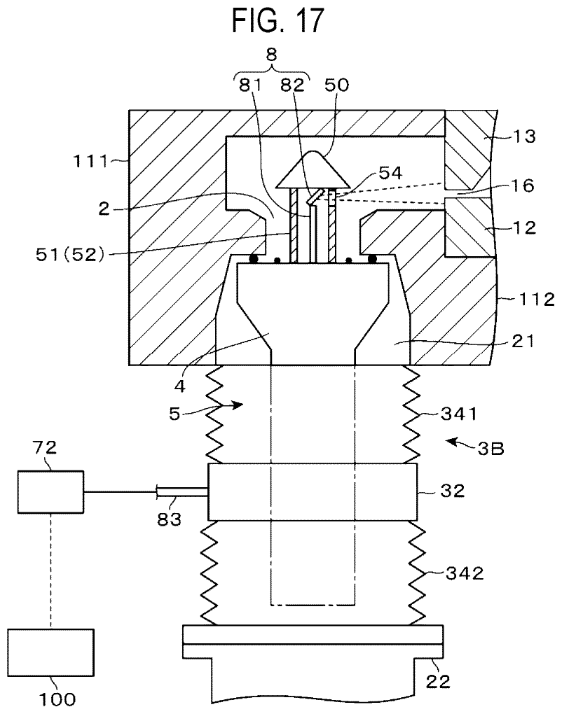

Although the examples using flexible linear members, like the fiber bundle 61 and the cable 71, disposed inside the mover 51 have been provided, the present disclosure is not limited to these configurations. A valve device 3B illustrated in FIG. 17 demonstrates an example where a rigid metallic tube 81 extending in a vertical direction is disposed inside the mover 51. A light guide member such as a lens is provided inside the tube 81. Then, a mirror 82 is provided at a tip of the tube 81 to change an optical path by 90 degrees. A detection part 8 in this example is configured to include the tube 81 and the mirror 82.

The detection unit 72 in this example includes a light source, and light from the light source passes through the light guide member inside the tube 81 and the mirror 82 and is emitted as illumination light toward the center of the processing container 11 through the opening 54 of the mover 51. Then, the mirror 82 reflects the gap 16 and the surrounding area thereof and the detection unit 72 is configured to acquire images of the gap 16 and the surrounding area thereof via the light guide member inside the tube 81.

According to this configuration, the rigid tube 81 surrounds the light guide member, and thus the light guide member does not move inside the second storage space 52 formed by the mover 51. This enables reducing a size of the second storage space 52 and further prevents the valve device 3 from becoming larger. In addition, in order not to interfere with the vertical movement of the mover 51, a base of the tube 81 is connected to a flexible light guide member 83 such as an optical fiber, allowing light guidance between the tube 81 and the detection unit 72 via the light guide member 83.

### <First Modification of Valve Device>

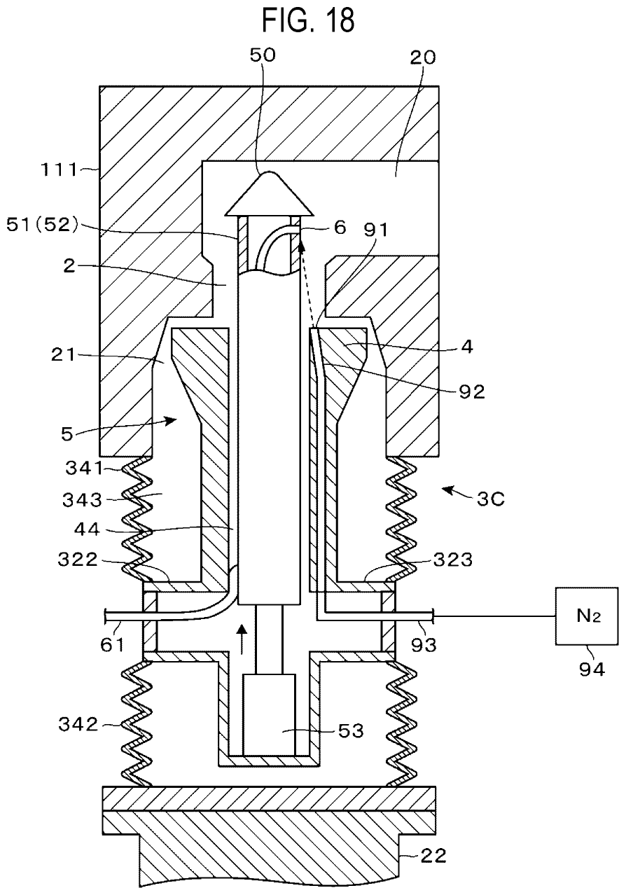

A first modification of the valve device is described with reference to FIG. 18. A valve device 3C in this example includes a supply port 91 for an anti-adhesion gas to prevent foreign matters from adhering to the valve body 5. For example, a gas flow path 92 is formed in the interior of the valve main body 4, and a tip of the gas flow path 92 opens to the planar portion 41 to form the supply port 91, which is configured to discharge the anti-adhesion gas toward the detection part 6 at the second position. A base of the gas flow path 92 is connected to a gas supply pipe 93, and via the gas supply pipe 93, is connected to a gas source 94 for the anti-adhesion gas, for example, an inert gas such as a nitrogen (N₂) gas. In this example, as illustrated in FIG. 18, the connecting member 323 of the support member 32 is also configured to include an internal space, enabling the gas supply pipe 93 to be connected to the gas source 94 provided outside the valve device 3C through the connecting member 323.

In this example, supplying the anti-adhesion gas to the detection part 6 when detecting the internal state of the processing container 11 by the detection part 6 prevents the process gas remaining in the processing container 11 from coming into contact with the detection part 6. As a result, deposition of the foreign matters on the detection part 6 is inhibited, allowing for stable detection and preventing particle generation.

### <Second Modification of Valve Device>

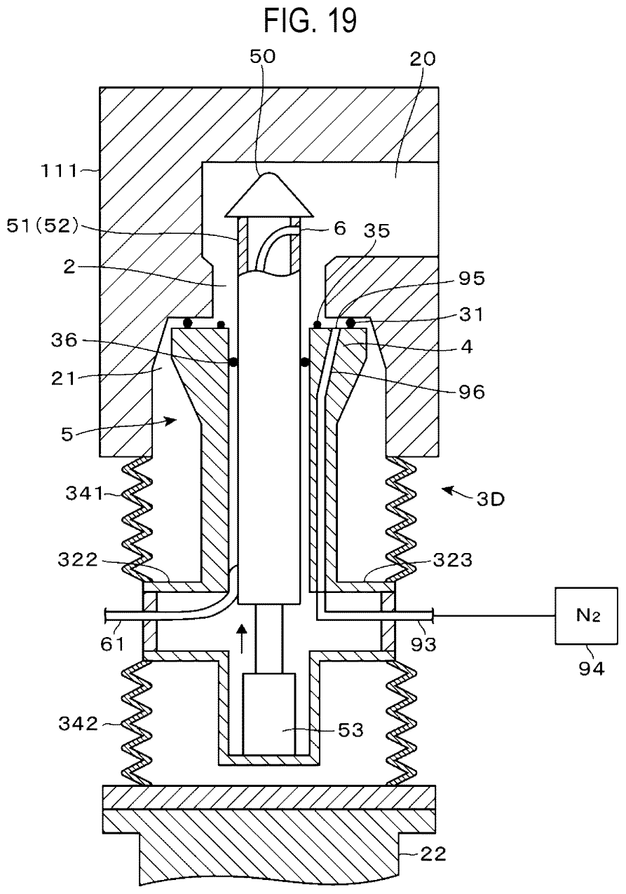

A second modification of the valve device is described with reference to FIG. 19. A valve device 3D in this example includes a supply port 95 formed at the upper surface of the valve main body 4, from which a N₂ gas is discharged as an anti-adhesion gas. Although it is already difficult for any matters derived from the process gas to adhere to the valve body 5 as described above, the discharge of N₂ gas in this manner further enhances the prevention of adhesion. In this example, the supply port 95 is formed at the planar portion 41 of the valve main body 4 between the first seal member 31 and the second seal member 35 to face the exhaust port 2, but the position thereof is not limited to this example. In addition, a flow path in the valve main body 4 that connects the supply port 95 to the gas source 94 is indicated as a gas flow path 96.

In the examples illustrated in FIGS. 18 and 19, the N₂ gas is discharged from the supply port 95 at least during the processing of the wafer W, and the discharged gas flows around the valve body 5 and is removed by exhaust from the exhaust path 21. Therefore, as already described, the N₂ gas is supplied to the detection part 6 and the valve body 5. At this time, the N₂ gas also flows to areas where the first to third seal members 31, 35 and 36 are provided, preventing deposition of the foreign matters in these areas.

In addition, the first and second modifications illustrated in FIGS. 18 and 19 are configured similarly to the first and second embodiments, except for the addition of the supply ports 91 and 95 for the anti-adhesion gas. Further, they are applicable to the valve devices 3, 3A and 3B of the first and second embodiments, regardless of whether the detection parts 6, 7 and 8 perform detection with or without scanning.

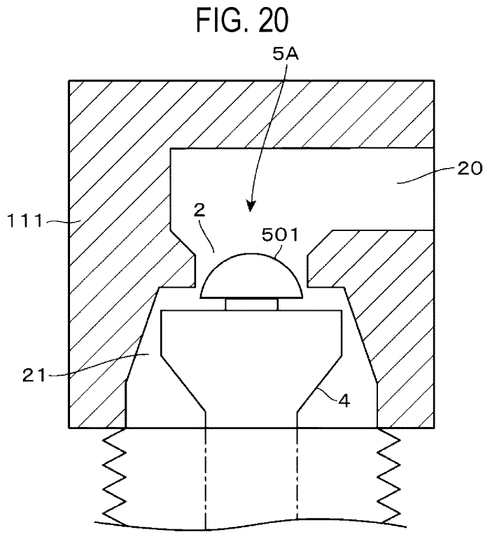

In the above, a valve body 5A, as illustrated in FIG. 20, is not limited to a configuration where a cap 501 at the top thereof is shaped as an approximately conical shape with a rounded top as illustrated in FIGS. 4 and 5, and may alternatively be hemispherical with a flat lower surface. This shape may also reduce resistance of the valve body 5A to the gas flowing from above the valve body 5A and guide the gas to quickly flow it into the exhaust path 21.

Further, in the configuration where the plurality of exhaust paths 21 are connected to the exhaust port 2 that opens into the processing container 11, it is not necessary to provide all of the exhaust paths 21 with the valve device of the present disclosure. For example, in the substrate processing apparatus 1 illustrated in FIG. 1, it may be sufficient to provide three or more exhaust paths 21 selected from eight exhaust paths 21 with the valve device 3 with the detection part 6. In this case, there is also the exhaust path 21 that is opened or closed by the valve device without the detection part 6, but this valve device is configured similarly to the above-described valve device 3, except that the valve main body 4 does not include the detection part 6, first storage space 44, mover 51, and hollow connecting member 322.

Furthermore, in the present disclosure, an ultrasonic sensor may be used as the detection part, instead of the optical fiber sensor. In this case, for example, as in the first embodiment, the mover 51 is positioned at the second position, and ultrasonic waves are emitted from the ultrasonic sensor toward the processing container 11 while lowering the valve main body 4 to perform scanning. Then, by acquiring the reflected ultrasonic waves, a height position at which reflection of the ultrasonic waves occurs may be detected, allowing detection of the size of the gap 16. However, it is desirable to perform optical detection as previously described for higher accuracy detection due to high diffusivity of ultrasonic waves with distance from a radiation source.

Further, the upper structure of the present disclosure does not necessarily need to be configured as a gas supplier as long as it is configured to create the processing space 10 for the wafer W with the stage 12. For example, the upper structure may be configured as an upper electrode that generates a plasma in cooperation with the stage 12, which serves as a lower electrode. Then, the process gas may be supplied to the processing space 10 created between the upper structure and the stage 12 by using a gas nozzle or the like.

Furthermore, if the internal state of the processing container 11 is the distance between the upper structure and the stage 12 and if control over substrate processing involves a change in this distance, a lift serving as a distance changer may be provided on the side of the stage 12 to adjust this distance by moving the stage 12 to come into contact with or be separated from the upper structure.

In the above-described embodiments, the substrate processing apparatus is used for film formation by ALD, but may also be an apparatus performing plasma ALD. Further, as long as an apparatus is capable of supplying a gas to the processing space created between the upper structure and the stage and exhausting the gas through the gap 16 formed to surround the processing space 10 to process the wafer W, the apparatus is not limited to the apparatus performing the film formation by ALD.

The shape of the processing space in the processing container 11 of the substrate processing apparatus 1 and the number or layout of exhaust ports 2 as described above are examples and are not limited to the above-described configurations.

Further, the second driver 53 may be a motor, and the first storage space 44 may be configured as a sealed space, where air is supplied to the first storage space 44 to raise the second storage space 52 to the second position and is discharged from the first storage space 44 to lower it to the first position. Furthermore, a heater may be stored in the second storage space 52. Further, the shape of the valve body 5 is also not limited as long as it is able to accommodate the mover 51 and the detection part 6.

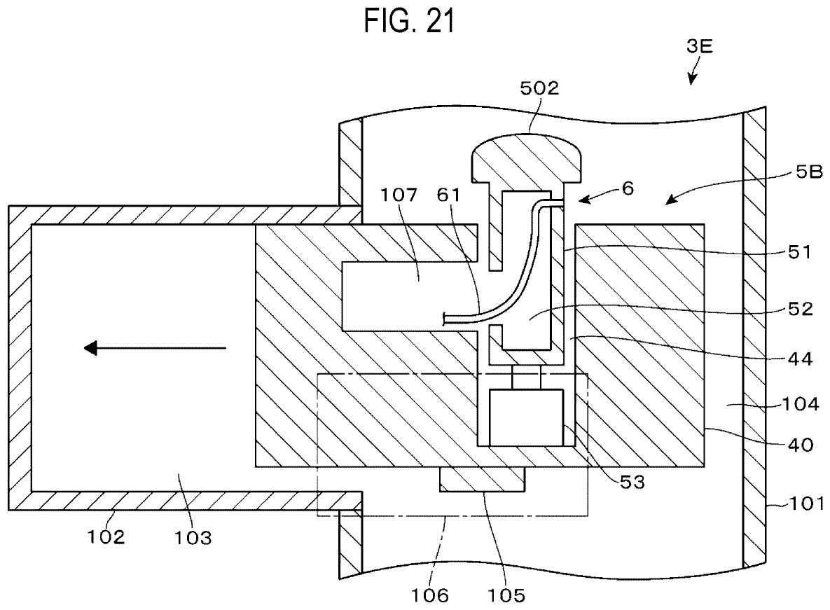

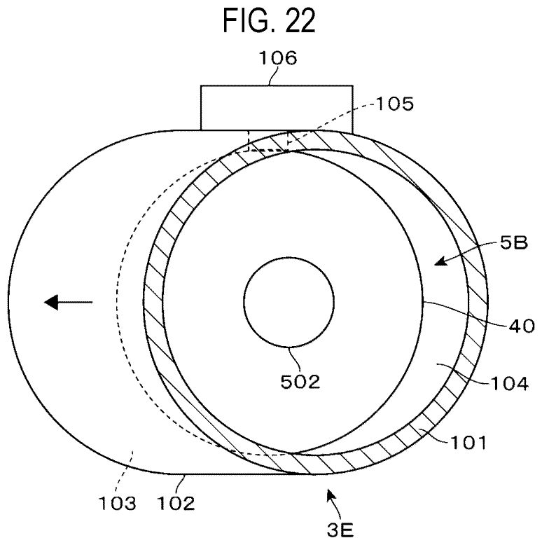

Herein, a valve device 3E, which is a configuration example of another valve device, is described, focusing on differences from the valve device 3 of the first embodiment, with reference to a vertical cross-sectional view in FIG. 21 and a plan view in FIG. 22. In the drawings, 101 denotes an upright exhaust pipe with an upper end connected to the exhaust port 2, and exhaust by the exhauster 23 is performed from a lower end of the exhaust pipe 101. A space forming member 102 is provided on an outer sidewall of the exhaust pipe 101, and a storage space 103 formed in an interior of the space forming member 102 communicates with a flow path 104 inside the exhaust pipe 101. A valve body 5B including a valve main body 40 and the mover 51 is provided at the flow path 104. Unlike the previous examples, a cap 502 of the mover 51 has a convex lens shape at the top thereof in a side view.

The valve main body 40 is connected to a driver 106, which is provided outside the exhaust pipe 101, through a connector 105. The driver 106 allows the valve main body 40 to move horizontally to open or close the flow path 104, and may appropriately adjust a penetration depth of the valve main body 40 into the storage space 103. An opening area of the flow path 104 varies according to this penetration depth, thereby adjusting the internal pressure of the processing space 10 in the processing container 11 as in the first embodiment. Accordingly, a movement direction of the valve body for the opening and closing of the flow path and the adjustment of the opening degree in the valve device 3E differs from that in the valve device 3 described previously. Accordingly, the present technology is not limited to applications in valve devices in which the valve body moves in the vertical direction as previously described.

In addition, the valve main body 40, which is circular in a plan view, has the same first storage space 44 as the valve main body 4 of the above-described embodiments, and the gap 16 may be detected, similarly to the first embodiment, as the mover 51 is raised from the first position illustrated in FIG. 21 to the second position by the second driver 53 provided in the first storage space 44. The base of the fiber bundle 61 constituting the detection part 6 is drawn out from the mover 51 and is directed toward a space 107, which extends horizontally from the first storage space 44, and then passes through flow paths (not illustrated) inside the connector 105 and the driver 106, thereby being drawn out from the exhaust pipe 101 and connected to the detection unit 62 (not illustrated in FIGS. 21 and 22).

In the above, the substrate has been exemplified as a wafer, but other workpieces processed in the processing container 11 may include a substrate for manufacturing a flat panel display, a substrate for manufacturing an exposure mask used in photolithography, and a dummy substrate processed for the purpose of testing or setting processing parameters in a substrate processing apparatus.

The embodiments disclosed herein should be considered as illustrative and not restrictive in all respects. The above embodiments may be omitted, replaced or modified in various ways without departing from the scope or spirit of the appended claims.

According to the present disclosure, in a processing apparatus equipped with a processing container for performing a workpiece, a detection part provided in a valve device may detect an internal state of the processing container.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A valve device provided in a processing apparatus including a processing container for processing a workpiece, the valve device comprising:
a valve body including a valve main body configured to open or close an exhaust path connected to an exhaust port that opens into the processing container and a mover provided in the valve main body to move between a first position at the exhaust path and a second position upstream of the first position and outside the exhaust port; and
a detector including a detection part provided in the mover to detect an internal state of the processing container while the mover is at the second position.

2. The valve device of claim 1, wherein the valve main body is stoppable at each of a plurality of open positions that open the exhaust path, and
wherein an internal pressure of the processing container is changed by movement of the valve main body between the plurality of open positions.

3. The valve device of claim 1, wherein the detection part serves to perform optical detection.

4. The valve device of claim 1, wherein the valve main body includes a first storage space that stores the mover and forms a movement path for the mover, and a driver that moves the mover is provided in the first storage space.

5. The valve device of claim 1, wherein the valve main body includes a first storage space that stores the mover and forms a movement path for the mover, and
wherein the mover forms a second storage space that is partitioned from the first storage space and stores and protects the detection part.

6. The valve device of claim 1, wherein the valve body becomes a contracted state by the mover positioning at the first position while the exhaust path is open, and
wherein the valve body becomes an extended state by the mover positioning at the second position while the exhaust path is closed.

7. The valve device of claim 1, wherein the valve main body includes a supply port for an anti-adhesion gas of foreign matter to the valve body and a first storage space that stores the mover and forms a movement path for the mover, and
wherein, when the mover is at the second position, the detection part is located outside the first storage space and the supply port supplies the anti-adhesion gas toward the detection part.

8. A substrate processing apparatus comprising:
a processing container;
a stage provided in an interior of the processing container to place a substrate on the stage;
a gas supplier configured to supply a process gas for processing of the substrate on the stage;
an exhaust port that opens into the processing container to exhaust the process gas;
a valve device provided at an exhaust path connected to the exhaust port;
a valve body included in the valve device and including a valve main body configured to open or close the exhaust path and a mover provided in the valve main body to move between a first position at the exhaust path and a second position upstream of the first position and outside the exhaust port;
a detector included in the valve device and including a detection part provided in the mover to detect an internal state of the processing container while the mover is at the second position; and
a controller configured to output a control signal to perform control over the processing of the substrate based on a detection result from the detection part.

9. The substrate processing apparatus of claim 8, wherein the processing container is provided with an upper structure facing the stage from above.

10. The substrate processing apparatus of claim 9, wherein the upper structure is the gas supplier and is provided with an outlet that discharges the process gas toward the stage.

11. The substrate processing apparatus of claim 9, wherein the internal state of the processing container is a distance between the upper structure and the stage, and a distance changer is provided to change the distance, and
wherein the control over the processing of the substrate is adjustment of the distance when the process gas is supplied to the substrate.

12. The substrate processing apparatus of claim 9, wherein the exhaust port opens upward, and
wherein the second position is located laterally relative to the upper structure and the stage and above the first position.

13. The substrate processing apparatus of claim 8, wherein the valve main body is stoppable at each of a plurality of open positions that open the exhaust path,
wherein an internal pressure of the processing container is changed by movement of the valve main body between the plurality of open positions, and
wherein the control over the processing of the substrate is a change in setting of the plurality of open positions according to a set internal pressure of the processing container.

14. A substrate processing method comprising:
placing a substrate on a stage provided in an interior of a processing container;
performing a process by supplying a process gas from a gas supplier to the substrate on the stage;
exhausting the process gas from an exhaust port that opens into the processing container;
opening or closing an exhaust path connected to the exhaust port by using a valve main body included in a valve body;
moving a mover, provided in the valve main body to constitute the valve body together with the valve main body, between a first position at the exhaust path and a second position upstream of the first position and outside the exhaust port;
detecting an internal state of the processing container while the mover is at the second position by using a detector including a detection part provided in the mover; and
controlling the process of the substrate based on a detection result from the detection part.

15. The substrate processing method of claim 14, wherein the internal state of the processing container is a distance between the stage and an upper structure provided in the processing container to face the stage from above.
